(19) United States
(12) Patent Application Publication
(10) Pub. No.: US 2007/0026544 A1
(43) Pub. Date: Feb. 1, 2007

(54) Impurity diffusion simulation method, impurity diffusion simulation apparatus, and impurity diffusion simulation program

(76) Inventor: Morikazu Tsuno, Shiga (JP)

Correspondence Address: MCDERMOTT WILL & EMERY LLP, 600 13TH STREET, N.W., WASHINGTON, DC, 20005-3096, US

(21) Appl. No.: 11/480,907

(22) Filed: Jul. 6, 2006

(30) Foreign Application Priority Data
Jul. 6, 2005 (JP) 2005-197799

(51) Int. Cl. H01L 21/66; H01L 21/425

(52) U.S. Cl. 438/14; 438/514

(57) ABSTRACT

The as-implanted concentration profile of impurity atoms in the semiconductor substrate is calculated, and a number of interstitial atoms to be generated in the semiconductor substrate by one impurity atom implanted with the ion implantation is set based on a peak concentration of the calculated as-implanted concentration profile of impurity atoms. The concentration profile of interstitial atoms generated in the semiconductor substrate is calculated based on the calculated as-implanted concentration profile of impurity atoms and the set number of interstitial atoms, and the concentration profile of impurity atoms in the semiconductor after the thermal processing is calculated based on the calculated as-implanted concentration profile of impurity atoms and the calculated concentration profile of interstitial atoms.

### CROSS-REFERENCE TO RELATED APPLICATION

The present application claims the benefit of patent application number 2005-197799, filed in Japan on Jul. 6, 2005, the subject matter of which is hereby incorporated herein by reference.

### FIELD OF THE INVENTION

The present invention relates to impurity diffusion simulation methods, impurity diffusion simulation apparatus, and impurity diffusion simulation programs, and in particular, the invention relates to impurity diffusion simulation methods, impurity diffusion simulation apparatus, and impurity diffusion simulation programs, whereby concentration profile of impurity atoms after the thermal processing can be predicted in consideration for point defects generated at the implantation of impurity atoms into a silicon substrate with ion-implantation.

### DESCRIPTION OF RELATED ART

In the process simulator, such as TSUPREM4 (Commercial Name) widely used, impurity diffusion equations considering interaction between impurity atoms and point defects in a semiconductor substrate are used to the impurity diffusion simulation for predicting the concentration profile of ion-implanted impurity atoms in a semiconductor substrate after the thermal processing.

The point defects are interstitial point defects that a semiconductor atom exists at an interstitial site, and vacancy point defects that a semiconductor atom does not exist at a lattice site. The impurity atoms implanted in the semiconductor substrate are diffused by interaction with the point defects in the thermal processing, (that is to say, enhanced diffusion).

The interaction between the impurity atoms and the point defects is generally well known as three mechanisms; kick-out mechanism, Frank-Turnbull mechanism, and normal vacancy diffusion mechanism. In the kick-out mechanism, an impurity atom moves between a lattice site and an interstitial site by the action of the interstitial semiconductor atoms (which is called interstitial atom, hereinafter). This diffusion mechanism is prominent in case of Boron (B) and Phosphorous (P) of which a covalent radius is smaller than that of Silicon. On the other hand, the Frank-Turnbull mechanism wherein an interstitial impurity atom is trapped in a vacancy and immobile there; and the normal vacancy diffusion mechanism wherein an impurity atom in a lattice site moves between its position and a neighboring vacancy; those diffusion mechanisms are prominent in case of Arsenic (As) of which covalent radius is larger than that of Silicon.

Where Jᵢ is a flux of diffusion caused by the interaction between the interstitial atoms and the impurity atoms, and Jᵥ is a flux of diffusion caused by the interaction between the vacancies and the impurity atoms, each flux is proportional to a difference between positions on a concentration Cₘ of activated mobile impurity atoms, as expressed by following equations.

$$\begin{matrix}{J}_{i} = - {D}_{ip} \{ \frac{ⅆ}{ⅆ x} ( {C}_{m} {K}_{i} ) \} & ( Equation 1 ) \\ {J}_{v} = - {D}_{vp} \{ \frac{ⅆ}{ⅆ x} ( {C}_{m} {K}_{v} ) \} & ( Equation 2 )\end{matrix}$$

In Equation 1, Dᵢₚ is a diffusion coefficient of the diffusion caused by the interaction between the interstitial atoms and the impurity atoms, and Kᵢ is a coefficient that is proportional to a reaction rate concerned with the interaction between the interstitial atoms and the impurity atoms. In Equation 2, Dᵥₚ is a diffusion coefficient of the diffusion caused by the interaction between the vacancies and the impurity atoms, and Kᵥ is a coefficient that is proportional to a reaction rate concerned with the interaction between the vacancies and the impurity atoms.

The above two equations is expanded to conservation of the particle number in a small area, and obtains a following equation that expresses a time-dependence of the impurity atoms concentration C.

$$\frac{ⅆ C}{ⅆ t} = - \frac{ⅆ}{ⅆ x} ( {J}_{i} + {J}_{v} ) \qquad ( Equation 3 )$$

In addition, the diffusion equation of point defects is expressed by following equation, where the interstitial atom concentration is Cᵢ and the vacancy concentration is Cᵥ.

$$\begin{matrix}\frac{ⅆ {C}_{i}}{ⅆ t} = - \frac{ⅆ}{ⅆ x} ( {D}_{i} {C}_{i}^{*} \frac{ⅆ}{ⅆ x} ( \frac{{C}_{i}}{{C}_{i}^{*}} ) ) & ( Equation 4 ) \\ \frac{ⅆ {C}_{v}}{ⅆ t} = - \frac{ⅆ}{ⅆ x} ( {D}_{v} {C}_{v}^{*} \frac{ⅆ}{ⅆ x} ( \frac{{C}_{v}}{{C}_{v}^{*}} ) ) & ( Equation 5 )\end{matrix}$$

In Equation 4, Dᵢ is a diffusion coefficient of interstitial atoms, and Cᵢ* is an equilibrium concentration of interstitial atoms. In Equation 5, Dᵥ is a diffusion coefficient of vacancies, and Cᵥ* is an equilibrium concentration of vacancies. The equilibrium concentration means point defects concentration balancing the formation with the annihilation of the point defects when the thermal processing is performed at high temperature.

When boundary conditions and initial conditions for the concentration profile of interstitial atoms, the concentration profile of vacancies, and the like, are given to the above equations, it is possible to simulate the concentration profile of impurity atoms in the semiconductor substrate (which is called ‘impurity profile’, hereinafter) at an arbitrary time. At simulating the impurity profile, the annihilation of the point defects is considered together with using models for recombining the interstitial atoms and the vacancies at an interface between a substrate and an oxide film formed on the substrate surface, recombining within the substrate, and the like.

When the impurity atoms are implanted into the semiconductor substrate with the ion-implantation, interstitial atoms to be generated in the ion-implantation process should be set as one of the initial conditions. The generation number of interstitial atoms in the ion-implantation process is expressed as “+1” model or “+N” model.

In the “+1” model, when one impurity atom is implanted into the semiconductor substrate, the impurity atom moves in the substrate damaging the crystal structure, and then stays at a lattice site when the crystal structure is restored by the thermal processing, hereupon an interstitial atom is generated.

In the “+N” model, as increased the mass of an element, silicon atoms are kicked out deeply in the substrate at the ion implantation. Even when the crystal structure is restored by the thermal processing, the silicon atoms do not stay on the lattice site and the interstitial atoms N are generated in the substrate. The generation number N of interstitial atoms in the “+N” model is expressed as follows:

$$N = 1 + \frac{0.42}{{R}_{p}^{3 / 4}} \sqrt{Em} \qquad ( Equation 6 )$$

Here, Rₚ is a projection range of impurity atom, E is a kinetic energy of impurity atom, and m is a mass of impurity atom.

Regarding the above impurity profile simulation, the fitting of the diffusion parameters, such as the diffusion coefficient and the equilibrium concentration, is made so as to project a predicted impurity profile onto a real impurity profile.

However, for example, when the impurity profile with a relatively high impurity concentration is predicted on conditions that the diffusion parameters are fit to a state that the concentration of impurity atoms in the substrate is relatively low, the predicted impurity profile is apt to indicate deeper diffusion than that of the real impurity profile. Therefore, in order to perform a high accuracy simulation, the above-mentioned diffusion parameters must be fit corresponding to the manufacturing process conditions such as the impurity implantation conditions and the thermal processing temperature.

A reason causing such disagreement of the impurity profiles is that the above diffusion equation cannot express enough a physical phenomenon in the impurity diffusion with the relatively high impurity concentration.

For instance, it is regarded that, when the impurity concentration is approximately 1×10²⁰ cm⁻³, an interstitial atom cluster is formed along {311} plane of a silicon crystal. The {311} cluster don't move during the thermal processing, and then it works as a supply source of the interstitial atom. Accordingly, when the {311} cluster is formed, the clustered interstitial atom does not contribute to the diffusion of impurity atoms. As a result, the diffusion of impurity atoms can be suppressed.

Various models are proposed in order to reflect the {311} cluster on the impurity diffusion simulation. For example, one of that is a model for immobilizing interstitial atoms in the case that the impurity concentration is more than specific concentration. Another of that is a model that has a time constant expressing the {311} cluster disappearance. In that model, {311} cluster is given by immobile interstitial atoms profile multiplied by a specific ratio in the impurity profile as implanted is using (referring to Japanese Laid-open Patent Publication No. 2000-91263).

By using the {311} cluster model, the impurity atom diffusion can be suppressed. Accordingly, in order to improve the disagreement on the simulation at the relatively high impurity concentration, even if the impurity concentration is smaller than 1×10²⁰ cm⁻³, it is regarded there is no formation of the {311} cluster, the impurity profile simulation is frequently performed using the {311} cluster model.

However, the use of the {311} cluster model makes the number of fitting parameters increase, and it is hard to perform the high accuracy simulation without fitting those parameters corresponding to respective manufacturing process.

Japanese Laid-open Patent Publication No. 11-97378 discloses a model for the purpose of improving the simulation accuracy irrespective of the manufacturing process in the case that arsenic atoms are implanted by the ion-implantation apparatus. In the model, the number of interstitial atoms generated per an implanted arsenic atom is limited to from 0.8 to 1.2 when the doses are not in excess of 1×10¹⁵ cm⁻², or to from 0.25 to 0.35 when the doses are in excess of 1×10¹⁵ cm⁻².

In this model, the increase of the doses makes the generation number of interstitial atoms decrease, so that it is possible to suppress the impurity diffusion at the high impurity concentration. Also, in this model, the number of fitting parameters does not increase, so that the impurity profile can be obtained accurately in a simple way throughout the wider range of the manufacturing conditions, as compared with a case applying the “+1” model or the “+N” model.

### SUMMARY OF THE INVENTION

In the prior art disclosed in Japanese Laid-open Patent Publication No. 11-97378, the impurity diffusion is calculated based on the as-implanted impurity profile. This calculation of the impurity diffusion uses the dose as a threshold value, however, the use of the dose as the threshold value is lack of a physical basis. In addition, in case of the as-implanted impurity profiles are different at the same doses, the predicted impurity profile after the thermal processing, using the model having the threshold value based on the implantation dose, has an error of result inevitably. For instance, in case of changing those of implantation energy, implantation angles, oxide film thicknesses for implanting ions through the oxide film on the surface of the substrate, and etc., the as-implanted impurity profiles differ each other even if the implantation doses are the same.

In addition, the practical method of manufacturing the semiconductor uses boron and phosphorous widely, however, there is no model by which the impurity profile of those elements can be obtained accurately. The foregoing prior art in Japanese Laid-open Patent Publication No. 11-97378 does not disclose the application for boron and phosphorous, too.

The present invention is suggested in view of the above-mentioned conditions, and has an object to provide impurity diffusion simulation method, impurity diffusion simulation apparatus, and impurity diffusion simulation program, whereby impurity profile can be predicted highly accurate throughout the wider range of the manufacturing conditions.

In order to achieve the above-mentioned objects, the invention employs following technical mans. The invention is assumed that an impurity diffusion simulation method predicts concentration profile of ion-implanted impurity atoms in a semiconductor substrate, which is performed a thermal processing after the ion-implantation into the semiconductor substrate, based on an impurity diffusion equation considering point defects. In the method, as-implanted concentration profile of impurity atoms in the semiconductor substrate is calculated, and a number of interstitial atoms to be generated in the semiconductor substrate by one impurity atom implanted with the ion implantation is set based on a peak concentration of the calculated as-implanted impurity atom concentration profile. Next, concentration profile of interstitial atoms generated in the semiconductor substrate is calculated based on the calculated as-implanted impurity atom concentration profile and the set number of interstitial atoms. Then, the concentration profile of impurity atoms in the semiconductor after the thermal processing is calculated based on the calculated as-implanted concentration profile of impurity atoms and the calculated concentration profile of interstitial atoms.

The number of interstitial atoms to be generated by one impurity atom is set to a value univocally determined depending on only the peak concentration corresponding to a impurity atom type, when the peak concentration is a predetermined threshold value or more, and to a value univocally determined based on kinetic energy, mass, and projection range of impurity atom, when the peak concentration is less than the predetermined threshold value. Instead of such configuration, the generation number may be set to a value univocally determined based on a specific value, when the peak concentration is less than the predetermined threshold value.

A diffusion coefficient and an equilibrium concentration for the impurity diffusion equation are determined based on real impurity concentration profile after the thermal processing in a semiconductor substrate having the as-implanted peak concentration of impurity atoms less than the threshold value.

In accordance with another aspect of the present invention, there is provided an impurity diffusion simulation apparatus for the simulation method. The apparatus has a unit configured to calculate as-implanted concentration profile of impurity atoms in the semiconductor substrate, and a unit configured to set a number of interstitial atoms to be generated in the semiconductor substrate by one impurity atom implanted with the ion implantation, based on a peak concentration of the calculated as-implanted impurity atom concentration profile. In addition, the apparatus has a unit configured to calculate concentration profile of interstitial atoms generated in the semiconductor substrate based on the calculated as-implanted impurity atom concentration profile and the set number of interstitial atoms, and a unit configured to calculate the concentration profile of impurity atoms in the semiconductor after the thermal processing, based on the calculated concentration profile of impurity atoms and the calculated concentration profile of interstitial atoms. Moreover, in this specification, the unit configured to calculate as-implanted concentration profile of impurity atoms corresponds to an implantation profile calculation unit, and the unit configured to set a number of interstitial atoms to be generated by one impurity atom corresponds to an interstitial atom generation number setting unit. In addition, the unit configured to calculate concentration profile of interstitial atoms generated in the semiconductor substrate corresponds to an interstitial atom profile calculation unit, and the unit for calculating the concentration profile of impurity atoms in the semiconductor after the thermal processing corresponds to a diffusion calculation unit.

In accordance with still another aspect of the invention, there is provided a program for causing a computer to execute the impurity diffusion simulation method.

In the present invention, in a high concentration range in which the as-implanted peak concentration of impurity atoms is in excess of a specific threshold value, the number of interstitial atoms generated by the implantation of one impurity atom is set to a value univocally determined only by the impurity atom type and the peak concentration. Then, by solving the well-known diffusion equation considering the interstitial point defects, the concentration profile of impurity atoms after the thermal processing is predicted. Therefore, without depending on the semiconductor manufacturing conditions, it is possible to perform the high accuracy impurity diffusion simulation with ease. In addition, the dependence of the generation number in the high concentration range on the peak concentration is optimized using the optimal values of the diffusion parameters calibrated to the low concentration range, so that the concentration profile of impurity atoms after the thermal processing can be predicted accurately in wide manufacturing conditions, such as, from the low concentration range to the high concentration range.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a flowchart showing an impurity diffusion simulation that relates to an embodiment of the present invention.

FIG. 2 is a flowchart showing an impurity diffusion simulation that relates to an embodiment of the present invention.

FIG. 3 is a functional block diagram of impurity diffusion simulation apparatus that relates to an embodiment of the present invention.

FIG. 4 is a diagram showing calculated impurity profiles in a low concentration range that relates to an embodiment of the present invention.

FIG. 5 is a diagram showing calculated impurity profiles in a high concentration range that relates to an embodiment of the present invention.

FIG. 6 is a diagram showing the dependence of the generation number of interstitial atoms per an impurity atom in the high concentration range on the peak concentration, which is applied to an embodiment of the present invention.

FIGS. 7A and 7B are an example of the impurity diffusion simulation of the invention.

FIGS. 8A and 8B are an example of the impurity diffusion simulation of the invention.

FIGS. 9A and 9B are an example of the impurity diffusion simulation of the invention.

FIGS. 10A and 10B are an example of the impurity diffusion simulation of the invention.

FIGS. 11A and 11B are an example of the impurity diffusion simulation of the invention.

FIGS. 12A and 12B are an example of the impurity diffusion simulation of the invention.

FIGS. 13A and 13B are an example of the impurity diffusion simulation of the invention.

FIGS. 14A and 14B are an example of the impurity diffusion simulation of the invention.

### DETAILED DESCRIPTION OF THE PREFERRED EMBODIMENT

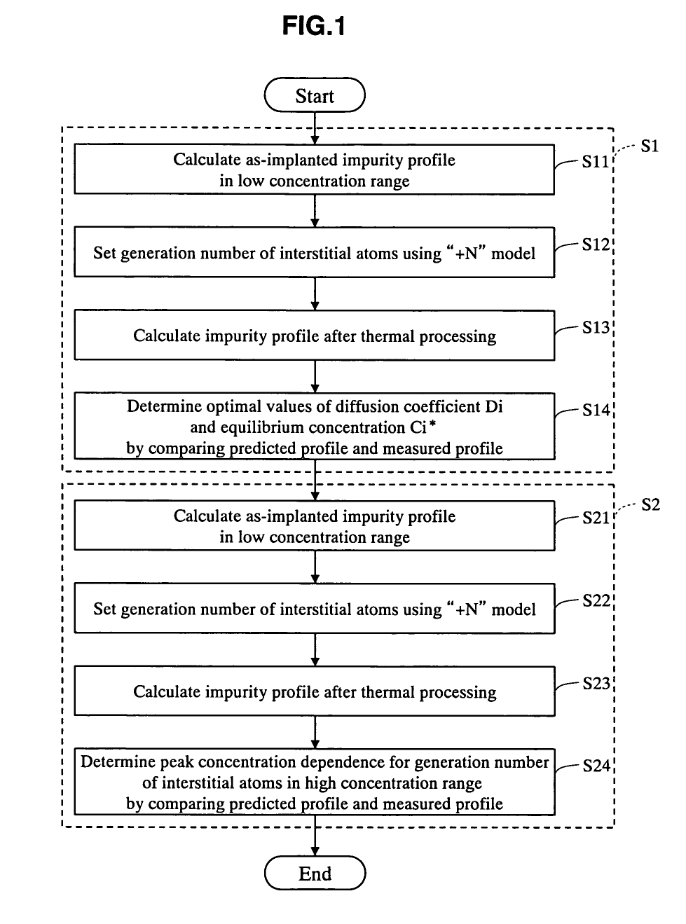

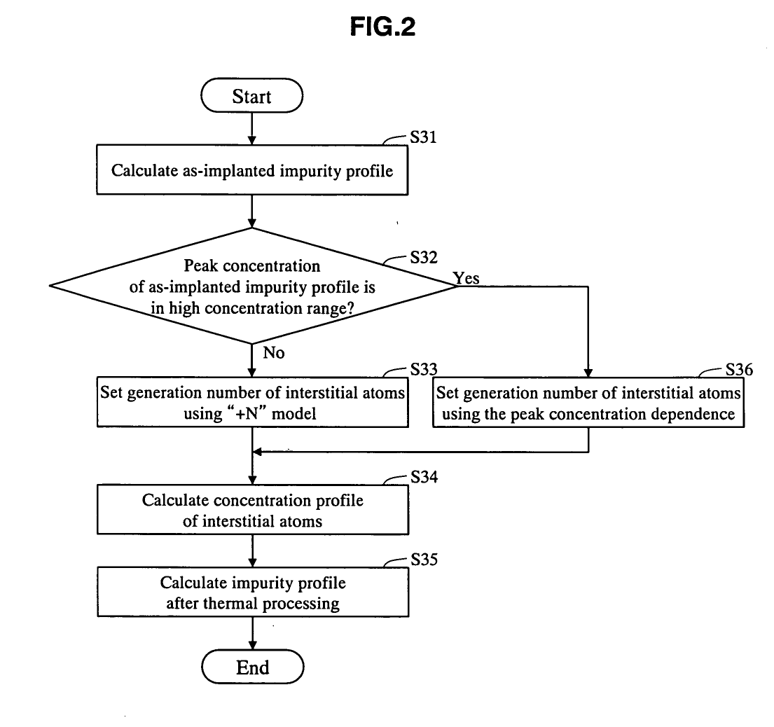

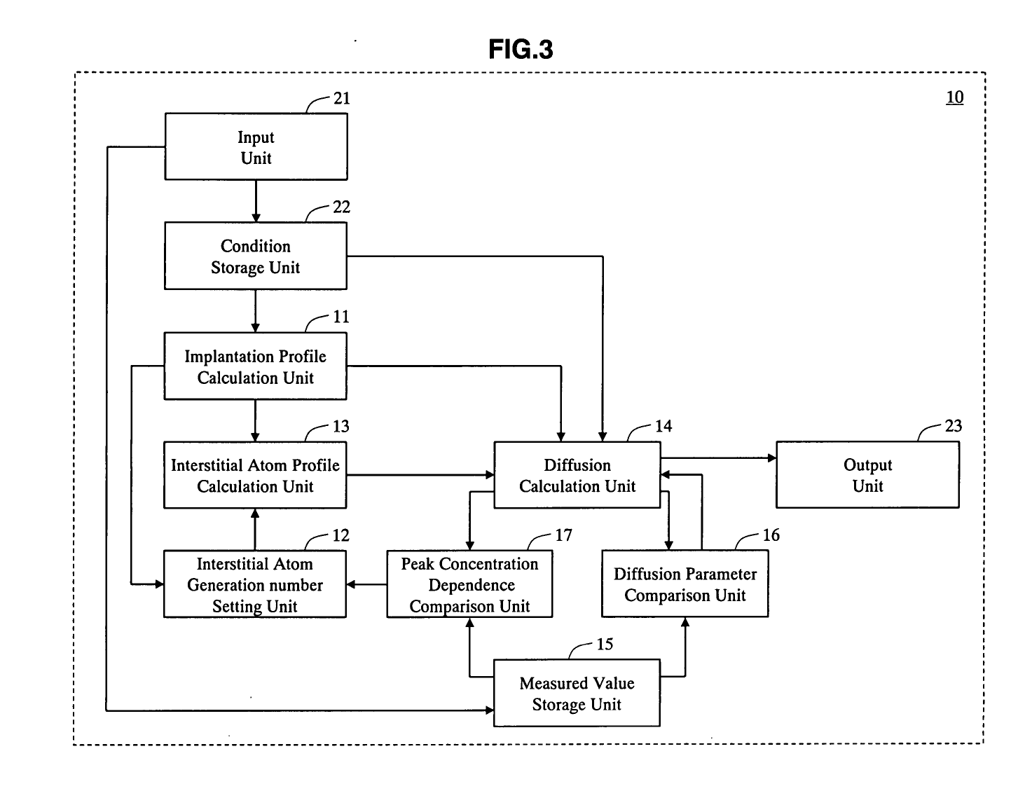

A detailed description is provided hereafter of an embodiment of the present invention based on cases of calculating the impurity profile of boron implanted in a silicon substrate with refer to drawings. FIG. 1 and FIG. 2 are flowcharts showing process of the impurity diffusion simulation method that relates to this embodiment. FIG. 3 is a functional block diagram of an impurity diffusion simulation apparatus that relates to this embodiment.

As shown in FIG. 3, the impurity diffusion simulation apparatus 10 in this embodiment has an implantation profile calculation unit 11, an interstitial atom generation number setting unit 12, an interstitial atom profile calculation unit 13, and a diffusion calculation unit 14.

The implantation profile calculation unit 11 calculates the concentration profile of impurity atoms (impurity profile) in the silicon substrate after the implantation according to the implantation conditions; a type of impurity atom implanted with the ion implantation, an implantation energy, an implantation doses, an implantation angle at the ion implantation (a tilt angle and a twist angle of the silicon substrate), and a film thickness of an oxide film on the silicon substrate surface. This calculation is done using Monte Carlo method and distribution functions such as Pearson function obtained based on data measured by the Secondary Ion Mass Spectroscopy (SIMS), for example. In this embodiment, the implantation conditions are inputted direct through an input unit 21 by a user, or inputted by the user as a file recognizable by the impurity diffusion simulation apparatus 10, and are stored in a condition storage unit 22.

The interstitial atom generation number setting unit 12 sets the number of interstitial silicon atoms to be generated in the silicon substrate by one impurity atom implanted with the ion implantation based on a peak concentration of as-implanted impurity profile calculated by the implantation profile calculation unit 11. In this invention, when the peak concentration of as-implanted impurity profile calculated by the implantation profile calculation unit 11 is less than a specific threshold value (which is called ‘low concentration range’, hereinafter), the interstitial atom generation number setting unit 12 sets the generation number of interstitial atoms based on the “+N” model, that is shown as Equation 6. On the other hand, when the peak concentration of as-implanted impurity profile calculated by the implantation profile calculation unit 11 is a specific threshold value and more (which is called ‘high concentration range’, hereinafter), the interstitial atom generation number setting unit 12 sets the value as an univocally determined value depending only on the peak concentration corresponding to the impurity atom type.

According to the generation number of interstitial silicon atoms per an impurity atom which is set by the interstitial atom generation number setting unit 12, the interstitial atom profile calculation unit 13 calculates the concentration profile of interstitial silicon atoms in the silicon substrate. Then, the diffusion calculation unit 14 calculates the impurity profile in the silicon substrate after the thermal processing by solving the respective diffusion equations expressed by Equations 1 to 5 by means of the numerical analysis method such as Newton's Law, based on the temperature and time of the thermal processing to be performed after the ion implantation. At this time, the as-implanted impurity profile calculated by the implantation profile calculation unit 11 and the concentration profile of the interstitial silicon atoms calculated by the interstitial atom profile calculation unit 13 are used initial conditions for solving. In the calculations of the impurity profile, it is considered the annihilation of the point defects with using models such as recombination of the interstitial atoms and the vacancies at an interface between the substrate and the oxide film formed on the substrate and in the substrate. However, this is not directly concerned with the present invention, and the detailed explanation is not made here.

In this embodiment, the thermal processing conditions are inputted direct through the input unit 21 by a user, or inputted by the user as a file recognizable by the impurity diffusion simulation apparatus 10, and are stored in the condition storage unit 22. The explanation regarding a diffusion parameter comparison unit 16 and a peak concentration dependence comparison unit 17 is provided hereinafter.

In case the impurity diffusion simulation is preformed by means of thus configured impurity diffusion simulation apparatus 10, the fitting of the parameters (which is called ‘calibration’, hereinafter) is done before the execution of the simulation as well as in the prior arts. FIG. 1 is a flowchart showing the calibration process executed on the impurity diffusion simulation apparatus 10 of this embodiment.

In the calibration process, the diffusion parameters of the interstitial silicon atoms to be used in the calculation by the diffusion calculation unit 14 are calibrated (FIG. 1, Step S1), and the dependence formula of the interstitial silicon atoms generation number on the peak concentration to be used by the interstitial atom generation number setting unit 12 in the high concentration range is derived (FIG. 1, Step S2). In this case, the diffusion parameters are the diffusion coefficient Dᵢ and the equilibrium concentration Cᵢ* in Equation 4.

The calibration of the diffusion parameters are performed by the diffusion parameter comparison unit 16 comparing the real impurity profile after the thermal processing and the impurity profile calculated by the diffusion calculation unit 14. For instance, such comparison is performed by fitting, wherein the diffusion parameter Dᵢ and the equilibrium concentration Cᵢ* are used as variables (fitting parameters), the calculated impurity profile, which is calculated by the impurity diffusion simulation apparatus 10 under the same implant conditions as the real profile, to the real impurity profile by means of the least squares method. The real impurity profile in the silicon substrate can be measured by SIMS and the like, which is stored in a measured profile storage unit 15.

As described above, where the impurity atoms are implanted in the semiconductor substrate with the ion implantation, the diffusion of impurity atoms in the semiconductor substrate during the thermal processing is governed by the enhanced diffusion. Also, in the case that the impurity atoms are boron, the main diffusion mechanism of the impurity atoms is the kick-out mechanism. Therefore, by fitting only the diffusion coefficient Dᵢ and the equilibrium concentration Cᵢ* in Equations 1 to 5, it is possible to express the diffusion of impurity atoms in the semiconductor substrate satisfactorily. At this fitting, the other parameters such as the diffusion coefficient Dᵥ and the equilibrium concentration Cᵥ* of the vacancies may use a value not diverted from a value in common use. It is possible to use a default parameter value in the process simulator TSUPREM4 as the other parameters, for instance.

In addition, this diffusion parameter calibration is performed under the conditions that an as-implanted peak concentration of impurity atoms is relatively low, that is, less than 5×10¹⁸ cm⁻³. As described above, when the as-implanted peak concentration of impurity atoms in the silicon substrate reaches 10²⁰ cm⁻³, the {311} cluster is formed. It is also reported that, when the ion implantation is performed so that the as-implanted peak concentration of impurity atoms is in excess of 2×10¹⁹ cm⁻³, the silicon substrate becomes amorphous state. The diffusion in the silicon substrate in which {311} cluster is formed, and the diffusion in the silicon substrate in which amorphous state is formed are not expressed precisely in the diffusion equations of Equations 1 to 5. Therefore, since the parameters include the {311} cluster and the amorphous state, when the diffusion parameters are derived under this conditions, it is hard to derive appropriate parameters.

Therefore, in this embodiment, the concentration value of 5×10¹⁸ cm⁻³ mentioned as above is used to a threshold value for distinguishing the high concentration range and the low concentration range, and the calibration of the diffusion parameters is performed based on the silicon substrate implanted with the impurity atoms with the concentration less than the threshold value. In this embodiment, based on the real silicon substrate to which boron is implanted with the implantation energy of 15 keV and the dose of 5.8×10¹² cm⁻³ (which is called ‘sample substrate’, hereinafter), the calibration of the diffusion parameters is executed. In this case, the as-implanted peak concentration of the boron in the silicon substrate is 8×10¹⁷ cm⁻³.

The above-mentioned thermal processing is performed as follows: annealing the sample substrate at 850° C. , forming an oxide film having a thickness of 10 nm at 850° C., and the oxide film is removed, and then another oxide film having a thickness of 3 nm is formed by the oxidization.

On the other hand, when the diffusion calculation unit 14 calculates the impurity profile after the thermal processing (which is called ‘as-annealed impurity profile’, hereinafter) to be used the calibration of the diffusion parameters, the implantation profile calculation unit 11 calculates the as-implanted impurity profile based on the implantation conditions stored in the condition storage unit 22 (FIG. 1, step S11). Next, the interstitial atom profile calculation unit 13 calculates the concentration profile of interstitial silicon atoms based on the calculated as-implanted impurity profile and the generation number of interstitial silicon atoms set by the interstitial atom generation number setting unit 12. At this time, since the peak concentration of boron in the silicon substrate is in the low concentration range, the interstitial atom generation number setting unit 12 sets the generation number of interstitial silicon atoms based on the “+N” model as shown Equation 6 (FIG. 1, step S12). In this case, the generation number of interstitial silicon atoms is 1.6.

The diffusion calculation unit 14 calculates the as-annealed impurity profile based on the thermal processing temperature and the thermal processing time when the sample substrate is annealed. This calculation uses the as-implanted impurity profile and the concentration profile of interstitial silicon atoms, as the initial conditions. In the calculation, the diffusion coefficient Dᵢ and the equilibrium concentration Cᵢ* are fitting parameters (FIG. 1, Step S13).

By calculating the error (mean square error, in this case) between thus calculated impurity profile and the real impurity profile obtained from the sample substrate, optimal values of the diffusion coefficient Dᵢ and the equilibrium concentration Cᵢ* are obtained (FIG. 1, step S14). In this calibration, the initial values of the diffusion coefficient Dᵢ and the equilibrium concentration Cᵢ* may be a value not diverted from a value in common use. For instance, the values may be a default parameter of the process simulator TSUPREM4.

In this embodiment, the optimal values of the diffusion coefficient Dᵢ and the equilibrium concentration Cᵢ*, that is the diffusion parameters, are values as shown following equations.
Dᵢ=3.5×10⁴ exp(−3.26/kT) [cm²/s] (Equation 7)
Cᵢ*=2.7×10³⁰ exp(−3.64/kT) [cm⁻³] (Equation 8)

In Equations 7 and 8, k is Boltzmann's constant, and T is an absolute temperature.

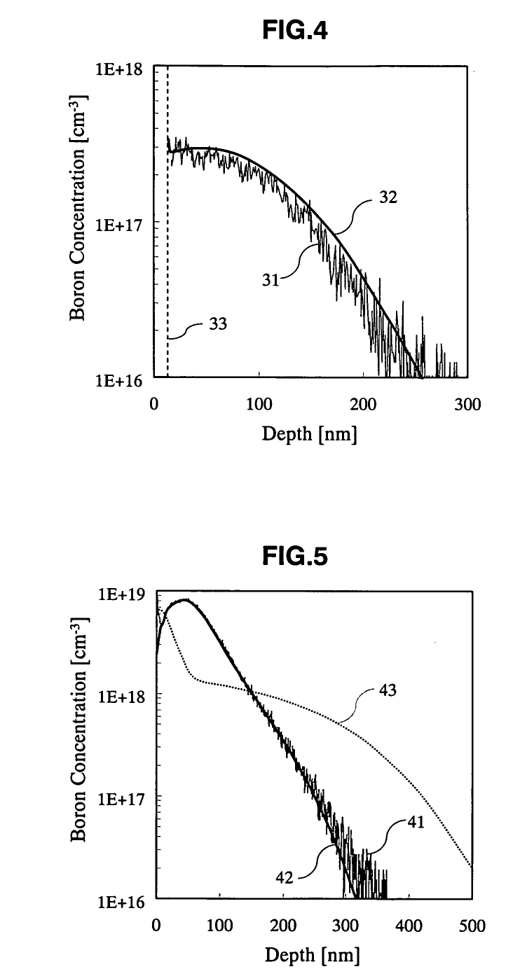

FIG. 4 shows the impurity profile of boron in the sample substrate obtained from SIMS (which is called an ‘measured profile’, hereinafter), and the impurity profile calculated by the impurity diffusion simulation apparatus 10 using the diffusion parameters shown in Equations 7 and 8 (which is called a ‘predicted profile’, hereinafter). In this specification, an origin of a depth direction of the impurity profile data is fixed on an underside of a surface oxide film existing before the ion implantation. Therefore, in case the film thickness of the surface oxide film increases due to the oxidation, the data of the impurity profile shows only data on positions deeper than the underside of the oxide film (dashed line 33, in FIG. 4).

As shown in FIG. 4, the measured profile 31 and the predicted profile 32 are identical properly, and the optimal values of the diffusion parameters shown in Equations 7 and 8 are seems to be appropriate. In addition, where the peak concentration of boron in the as-implanted silicon substrate is 5×10¹⁸ cm⁻³ or less, the predicted profile on another implantation conditions and another thermal processing conditions shows good agreement with the measured profile using the optimal values shown equations 7 and 8, which will be described later in examples.

After the calibration of the diffusion parameters of the interstitial silicon atoms (FIG. 1, Step S1) ends as described above, the interstitial atom generation number setting unit 12 derives a dependence formula of the interstitial atom generation number on the peak concentration, which is used in the high concentration range (FIG. 1, Step S2)

The derivation of dependence formula of the interstitial atom generation number on the peak concentration in the high concentration range is performed by peak concentration dependence comparison unit 17 comparing the real impurity profile of the semiconductor substrate, which is in the high concentration range, after the thermal processing and the impurity profile calculated by the diffusion calculation unit 14. For instance, such comparison is performed by fitting, wherein the generation number N of interstitial silicon atoms are used as fitting parameters, the calculated impurity profile, which is calculated by the impurity diffusion simulation apparatus 10 under the same implant conditions as the real profile, to the real impurity profile by means of the least squares method. The real impurity profile is stored in the measured profile storage unit 15.

In this embodiment, based on the measured profile of a sample substrate to which boron is implanted with the implantation energy of 15 keV and the dose of 1.0×10¹⁴ cm⁻³, the derivation of the dependence formula is executed. In this case, the as-implanted peak concentration of boron in the silicon substrate is 1.4×10¹⁹ cm⁻³, and the temperature of the annealing is 850° C.

When the diffusion calculation unit 14 calculates the as-annealed impurity profile to be used the derivation of the dependence formula, the as-implanted profile that the implantation profile calculation unit 11 calculates based on the implantation conditions (FIG. 1, step S21) and the concentration profile of interstitial silicon atoms that the interstitial atom profile calculation unit 13 calculates are initial conditions, in the same way as the calibration of the diffusion parameters in the low concentration range. Also, in this derivation, the optimal values obtained by the calibration in the low concentration range are used as the diffusion coefficient Dᵢ and the equilibrium concentration Cᵢ*. Moreover, in order to calculate the concentration profile of interstitial silicon atoms, an initial value of the generation number of interstitial atoms must be set. In this embodiment, a value calculated based on the “+N” model (Equation 6) is used as an initial value (FIG. 1, step S22). In this case, the generation number of interstitial silicon atoms is 1.1.

The diffusion calculation unit 14 calculates the as-annealed impurity profile based on the temperature and the time of the thermal processing performed on the sample substrate (FIG. 1, step S23), wherein the generation number N of interstitial silicon atoms are a fitting parameter. The error (mean square error, in this case) between the calculated impurity profile and the real impurity profile obtained from the sample substrate is calculated, and then the optimal value of the generation number N of interstitial silicon atoms is calculated (FIG. 1, step S24). In this case, the optimal value of the generation number N of interstitial atoms is 0.15.

FIG. 5 shows a measured profile 41 of the sample substrate with the peak concentration of born, 1.4×10¹⁹ cm⁻³, that is obtained from SIMS, and a predicted profile 42 calculated by the impurity diffusion simulation apparatus 10 using the diffusion parameters shown in Equations 7 and 8. Additionally, an impurity profile 43 as a comparative example is expressed by a dashed line, wherein the generation number N of interstitial silicon atoms is 1.1 based on the “+N” model. As shown in FIG. 5, while the impurity profile 43 as the comparative example is diffused deeper than the measured profile 41, the measured profile 41 and the predicted profile 42 show good agreement. This result shows that the reduction of the generation number of interstitial silicon atoms in the high concentration range makes it possible to express for suppressing the diffusion of impurity atoms caused by the amorphous of the silicon substrate and the like.

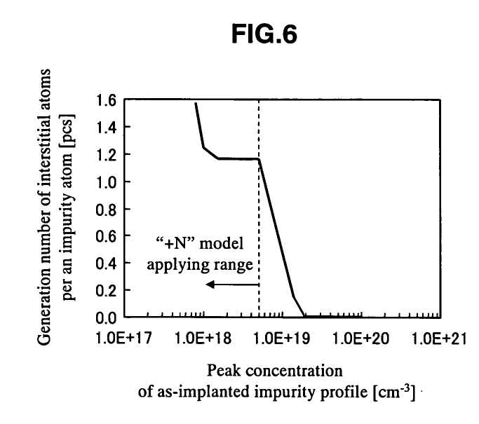

FIG. 6 shows dependence of the generation number N of interstitial silicon atoms on the peak concentration, which is obtained by fitting the generation number N of interstitial silicon atoms to silicon substrates having different peak concentration of impurity atoms. In result of the fitting, in the high concentration range as shown in FIG. 6, the generation number N of interstitial silicon atoms gradually reduces for the peak concentration of the as-implanted impurity atoms between 5×10¹⁸ cm⁻³ and 2×10¹⁹ cm⁻³. Also, it is understood that the generation number should be 0 in the high concentration not less than 2×10¹⁹ cm⁻³. Besides, in the low concentration range not more than 5×10¹⁸ cm⁻³, the generation number of interstitial silicon atoms calculated by the “+N” model can be applied as mentioned above.

According to the above result, the dependence formula of the generation number N of interstitial silicon atoms on the peak concentration in the high concentration range can be obtained as 1.166 where the peak concentration is 5×10¹⁸ cm⁻³ (obtained based on the “+N” model), and as 0 where the peak concentration is not less than 2×10¹⁹ cm⁻³. Where the peak concentration is between those values, the dependence formula can be obtained as an interpolation formula (for example, linear interpolation formula) of the generation number of interstitial silicon atoms obtained by comparing to the measured profile.

The dependence of the generation number of interstitial atoms on the peak concentration in the high concentration range thus obtained is appropriate, because it is possible to express the reduction of the number of diffusible interstitial atoms due to the amorphous of the silicon substrate and the {311} cluster formation in the high concentration range, and the predicted profile shows good agreement with the measured profile. The dependence formula of the generation number N of interstitial atoms on the peak concentration in the high concentration range is stored in the interstitial atom generation number setting unit 12. The interstitial atom generation number setting unit 12 also stores dependence formulas corresponding to the impurity atom types in addition to the boron dependence formula of the generation number N of interstitial atoms on the peak concentration.

After the calibration performed as above, it is possible to simulate the impurity diffusion under arbitrary implantation conditions and thermal processing conditions. FIG. 2 shows a flowchart of the process of the impurity diffusion simulation which can be performed after the calibration.

Using the input unit 21 of the diffusion simulation apparatus 10, a user inputs the implantation conditions, such as a type of impurity atom, impurity implantation energy, implantation dose, a film thickness of a surface oxide file, and implantation angle, and the thermal processing conditions, such as the thermal processing temperature and the thermal processing time concerned with the annealing for restoring the damaged crystal structure at the ion implantation and the thermal processing for the oxidation for forming an oxide film, which are stored in the condition storage unit 22.

The implantation profile calculation unit 11 calculates the as-implanted impurity profile based on the implant conditions stored in the condition storage unit 22. The implantation profile calculation unit 11 extracts a peak concentration of the calculated impurity profile (FIG. 2, step S31).

Next, the interstitial atom generation number setting unit 12 sets the generation number of interstitial silicon atoms based on the peak concentration of as-implanted impurity profile. That is to say, when the peak concentration is in the low concentration range, a value calculated on the “+N” model is set as the generation number (FIG. 2, step S32 No to S33). When the peak concentration is in the high concentration range, a value determined univocally only by the impurity atom type and the peak concentration using the peak concentration dependence formula of the generation number of interstitial silicon atoms derived corresponding to the impurity atom type is set as the generation number (FIG. 2, step S32 Yes to S36).

Based on the generation number of interstitial silicon atoms set by the interstitial atom generation number setting unit 12 and the as-implanted impurity profile calculated by the implantation profile calculation unit 11, the interstitial atom profile calculation unit 13 calculates the concentration profile of interstitial silicon atoms (FIG. 2, step S34).

Using as the initial conditions the as-implanted impurity profile calculated by the implantation profile calculation unit 11 and the concentration profile of interstitial silicon atoms calculated by the interstitial atom profile calculation unit 13, the diffusion calculation unit 14 calculates the diffusion equations expressed by Equations 1 to 5 according to the thermal processing conditions, and then the as-annealed impurity profile can be obtained (FIG. 2, step S35). At this time, the foregoing optimal values are used as the diffusion coefficient Dᵢ and the equilibrium concentration Cᵢ* in Equation 4. The as-annealed impurity profile thus calculated is outputted from an output unit 23 for a display or a file output.

As described above, the invention is configured so that the generation number of interstitial atoms generated in the implanted semiconductor substrate is set a value univocally determined based on only the as-implanted peak concentration of impurity profile and the impurity atom type in the high concentration range, such that the as-implanted peak concentration is not less than 5×10¹⁸ cm⁻³, and the as-annealed impurity profile is predicted by solving the well-known impurity diffusion equation considering the interstitial point defects. Therefore, even if the manufacturing method such as the impurity implantation conditions and the thermal processing conditions are modified in arbitrary, it is possible to predict the accurate impurity profile without needs of optimizing the parameters again. In addition, the simulation method of the invention described above is easy to apply to the process simulator for predicting the as-annealed impurity profile by solving the diffusion equation considering the interstitial point defects, such as TSUPREM4.

Furthermore, the implantation profile calculation unit 11, the interstitial atom generation number setting unit 12, the interstitial atom profile calculation unit 13, the diffusion calculation unit 14, the diffusion parameter comparison unit 16, and the peak concentration dependence comparison unit 17, they can be realized by a dedicated operation circuit, hardware provided with a processor and a memory such as RAM or ROM, and software stored in the memory and operable on the processor.

The program causing a computer to execute the process of the above-mentioned impurity diffusion simulation can be provided to any third party or persons concerned by using an electric communication line like the Internet, or by storing in a computer-readable recoding medium. For example, command codes of the program are expressed by electric signals, optical signals, or magnetic signals, and the like, to transmit them on carrier waves, whereby the program can be provided by the transmission medium like coaxial cables, copper wires, and optical fibers. Optical medium like CD-ROM, and DVD-ROM, magnetic medium like flexible disks, semiconductor memories like flash memories and RAM are available for the computer-readable recoding medium.

The followings relates to the results of comparing the as-annealed impurity profile predicted by the above-mentioned simulation apparatus 10 (the predicted profile) with the impurity profile of the real sample substrate formed in the same implant conditions and thermal processing conditions measured by SIMS under various conditions.

### EXAMPLE 1

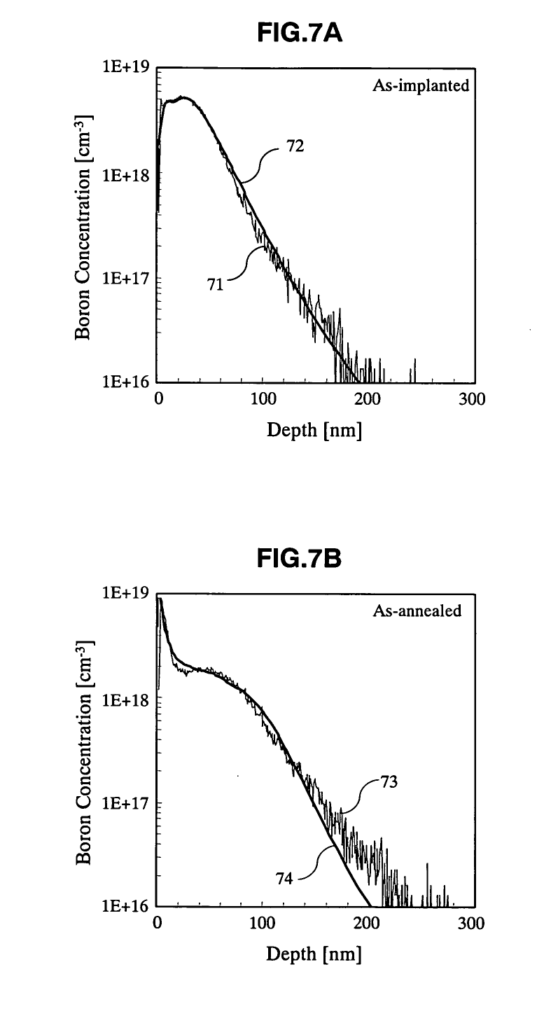

FIGS. 7A and 7B shows measured profile and predicted profile in case of implanting borondifluoride (BF₂) in a silicon substrate with 50 keV implantation energy and 3.2×10¹³ cm⁻² dose. FIG. 7A shows measured profile 71 and predicted profile 72 in as-implanted state. FIG. 7B shows measured profile 73 and predicted profile 74 in as annealed state. As the thermal processing in this example, the annealing is performed for 10 seconds at 850° C., and for 5 seconds at 1020° C. In this case, the peak concentration of as-implanted impurity profile is 5×10¹⁸ cm⁻³ and more, which is in the high concentration range, as shown in FIG. 7A. Accordingly, a value calculated based on the peak concentration dependence is set as the generation number of interstitial atoms.

According to FIG. 7B, it is understood that the predicted profile 74 corresponding to the measured profile 73 can be obtained.

### EXAMPLE 2

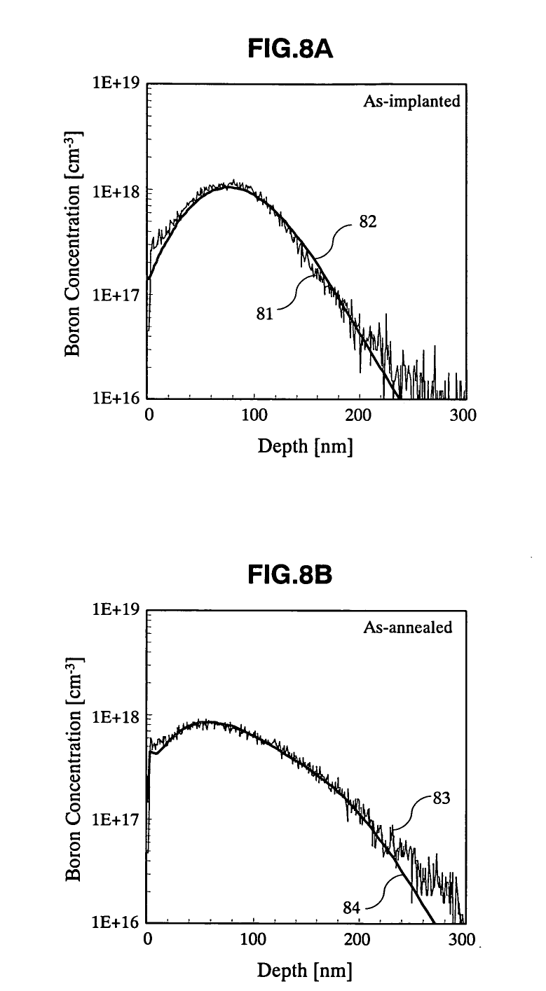

FIGS. 8A and 8B shows measured profile and predicted profile in case of implanting boron (B) in a silicon substrate with 25 keV implantation energy and 1.2×10¹³ cm⁻² dose. FIG. 8A shows measured profile 81 and predicted profile 82 in as-implanted state. FIG. 8B shows measured profile 83 and predicted profile 84 in as-annealed state. As the thermal processing in this example, the annealing is performed for 10 seconds at 850° C., and for 5 seconds at 1020° C. In this case, the peak concentration of as-implanted impurity profile is less than 5×10¹⁸ cm⁻³, which is the low concentration range, as shown in FIG. 8A. Accordingly, a value calculated based on the “+N” model (Equation 6) is set as the generation number of interstitial atoms.

According to FIG. 8B, it is understood that the predicted profile 84 corresponding to the measured profile 83 can be obtained.

### EXAMPLE 3

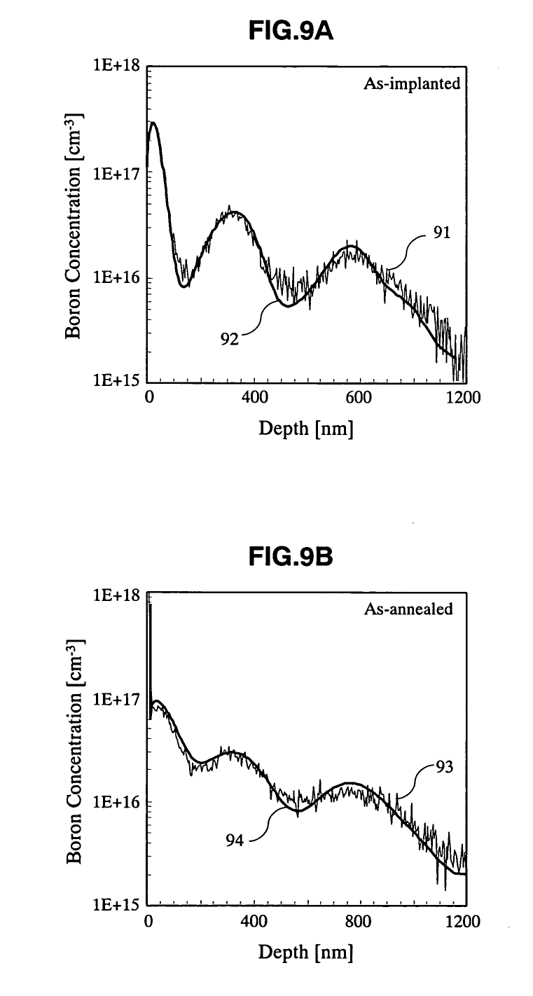

FIGS. 9A and 9B shows measured profile and predicted profile in case of implanting boron (B) in a silicon substrate with 10 keV implantation energy and 1.6×10¹² cm⁻² dose, 100 keV implantation energy and 8.0×10l cm⁻² dose, and 300 keV implantation energy and 4.0×10¹¹ cm⁻² dose, respectively. FIG. 9A shows measured profile 91 and predicted profile 92 in as-implanted state. FIG. 9B shows measured profile 93 and predicted profile 94 in as-annealed state. As the thermal processing in this example, the annealing is performed for 60 minutes at 850° C., and the oxidation processing is performed for 7.7 minutes at 900° C. (for forming 9 nm oxide film). In this case, the peak concentration of as-implanted impurity profile is less than 5×10¹⁸ cm⁻³, which is the low concentration range, as shown in FIG. 9A. Accordingly, a value calculated based on the “+N” model is set as the generation number of interstitial atoms.

According to FIG. 9B, it is understood that the predicted profile 94 corresponding to the measured profile 93 can be obtained.

### EXAMPLE 4

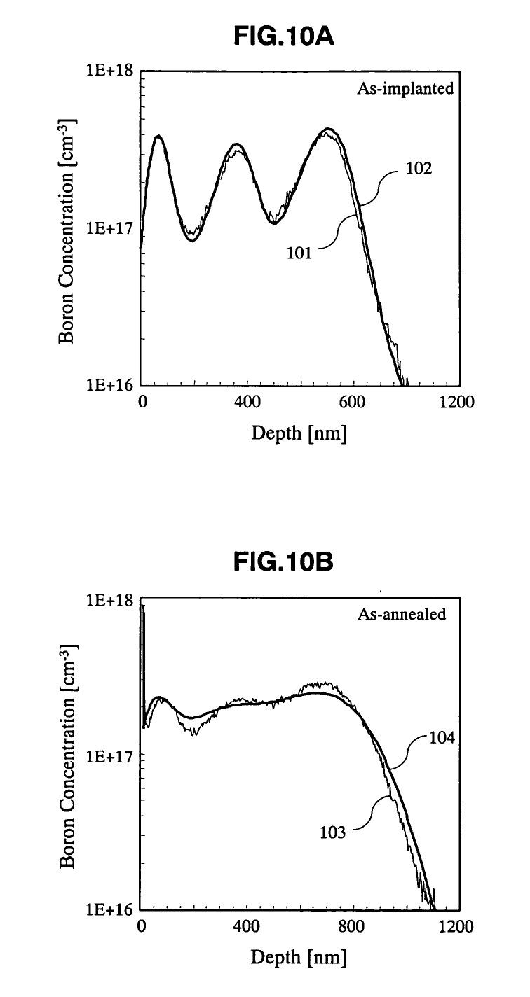

FIGS. 10A and 10B shows measured profile and predicted profile in case of implanting boron (B) in a silicon substrate with 20 keV implantation energy and 4.0×10¹² cm⁻² dose, 120 keV implantation energy and 6.0×10¹² cm⁻² dose, and 280 keV implantation energy and 1.0×10¹³ cm⁻² dose, respectively. FIG. 10A shows measured profile 101 and predicted profile 102 in as-implanted state. FIG. 10B shows measured profile 103 and predicted profile 104 in as-annealed state. As the thermal processing in this example, the annealing is performed for 60 minutes at 850° C., and the oxidation processing is performed for 7.7 minutes at 900° C. (for forming 9 nm oxide film). In this case, the peak concentration of as-implanted impurity profile is less than 5×10¹⁸ cm⁻³, which is the low concentration range, as shown in FIG. 10A. Accordingly, a value calculated based on the “+N” model is set as the generation number of interstitial atoms.

According to FIG. 10B, it is understood that the predicted profile 104 corresponding to the measured profile 103 can be obtained.

### EXAMPLE 5

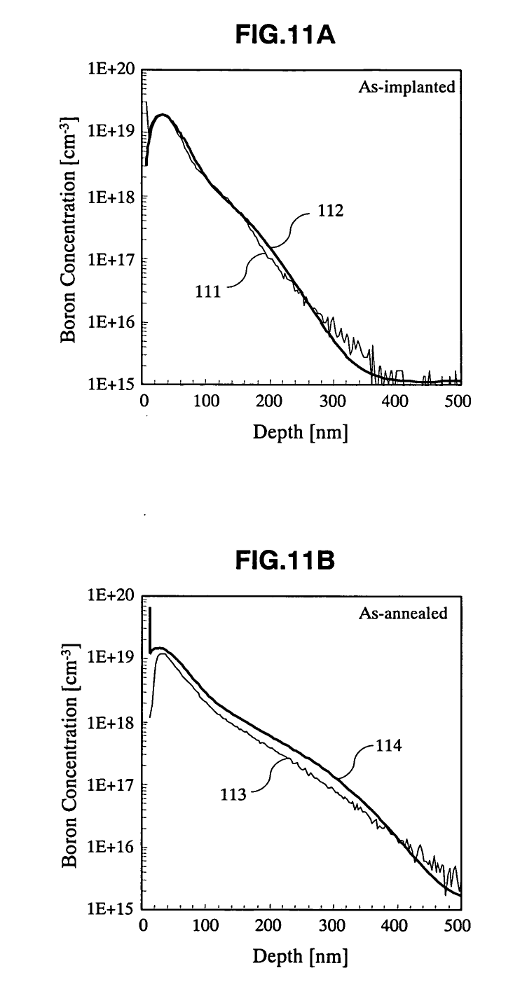

FIGS. 11A and 11B shows measured profile and predicted profile in case of implanting boron (B) in a silicon substrate with 8 keV implantation energy and 1.0×10¹⁴ cm⁻² dose, and 30 keV implantation energy and 1.0×10³ cm⁻² dose, respectively. FIG. 11A shows measured profile 111 and predicted profile 112 in as-implanted state. FIG. 11B shows measured profile 113 and predicted profile 114 in as-annealed state. As the thermal processing in this example, the annealing is performed for 45 minutes at 850° C. In this case, the peak concentration of as-implanted impurity profile is 5×10¹⁸ cm⁻³ and more, which is the high concentration range, as shown in FIG. 11A. Accordingly, a value calculated based on the peak concentration dependence is set as the generation number of interstitial atoms.

According to FIG. 11B, it is understood that the predicted profile 114 corresponding to the measured profile 113 can be obtained.

### EXAMPLE 6

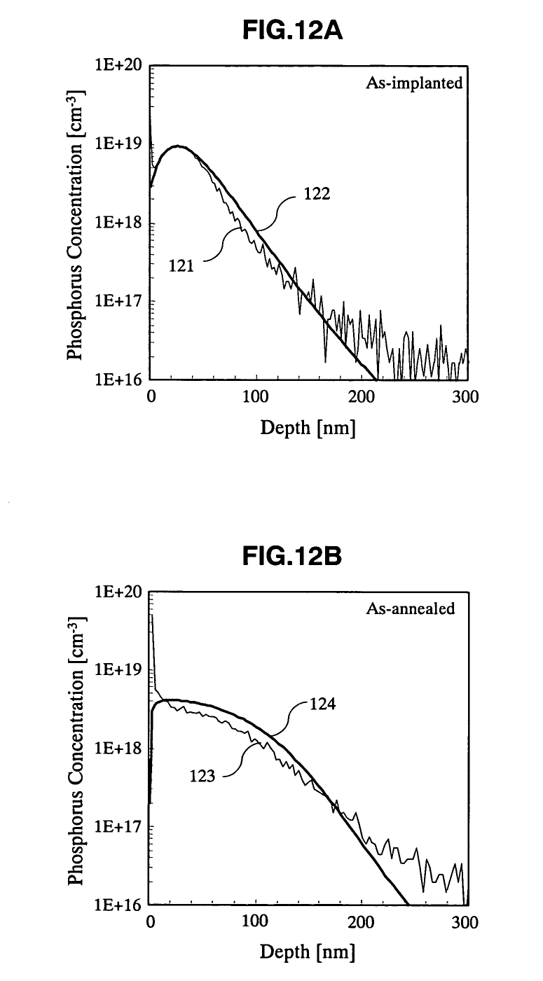

FIGS. 12A and 12B shows measured profile and predicted profile in case of implanting phosphorous (P) in a silicon substrate with 30 keV implantation energy and 6.0×10¹³ cm⁻² dose. FIG. 12A shows measured profile 121 and predicted profile 122 in as-implanted state. FIG. 12B shows measured profile 123 and predicted profile 124 in annealed state. As the thermal processing in this example, the annealing is performed for 10 seconds at 850° C., and for 5 seconds at 1020° C. In this case, the peak concentration of as-implanted impurity profile is 5×10¹⁸ cm⁻³ and more, which is the high concentration range, as shown in FIG. 12A. Accordingly, a value calculated based on the peak concentration dependence for phosphorous is set as the generation number of interstitial atoms.

According to FIG. 12B, it is understood that the predicted profile 124 corresponding to the measured profile 123 can be obtained.

### EXAMPLE 7

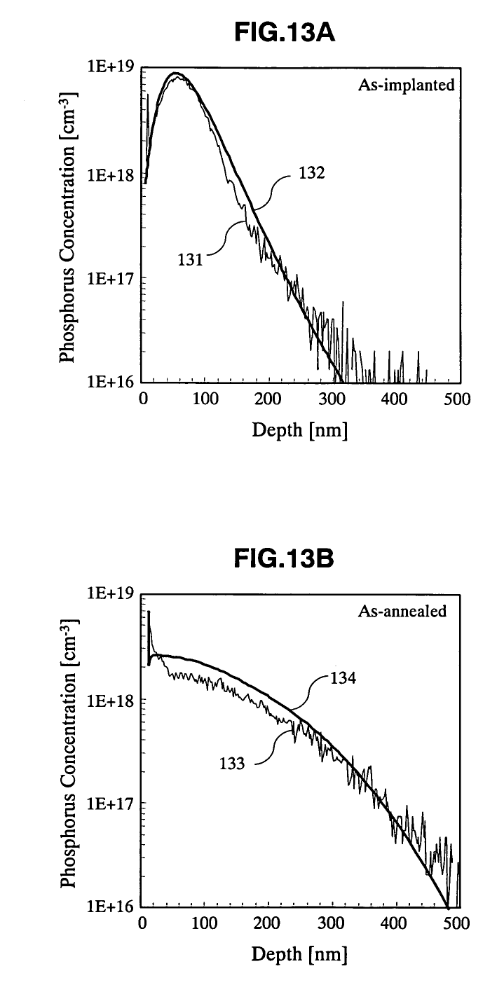

FIGS. 13A and 13B shows measured profile and predicted profile in case of implanting phosphorus (P) in a silicon substrate with 50 keV implantation energy and 8.0×10¹³ cm⁻² dose. FIG. 13A shows measured profile 131 and predicted profile 132 in as-implanted state. FIG. 13B shows measured profile 133 and predicted profile 134 in as-annealed state. As the thermal processing in this example, the annealing is performed for 45 minutes at 850° C. In this case, the peak concentration of as-implanted impurity profile is 5×10¹⁸ cm⁻³ and more, which is the high concentration range, as shown in FIG. 13A. Accordingly, a value calculated based on the peak concentration dependence for phosphorous is set as the generation number of interstitial atoms.

According to FIG. 13B, it is understood that the predicted profile 134 corresponding to the measured profile 133 can be obtained.

### EXAMPLE 8

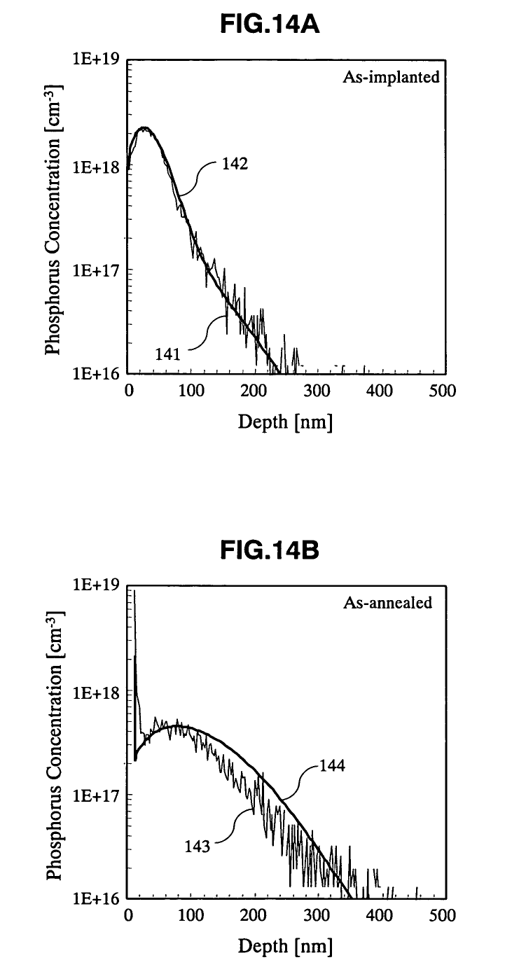

FIGS. 14A and 14B shows measured profile and predicted profile in case of implanting phosphorous (P) in a silicon substrate with 35 keV implantation energy and 1.4×10¹³ cm⁻² dose. FIG. 14A shows measured profile 141 and predicted profile 142 in as-implanted state. FIG. 14B shows measured profile 143 and predicted profile 144 in as-annealed state. As the thermal processing in this example, the annealing is performed for 60 minutes at 850° C., and the oxidation processing is performed for 7.7 minutes at 900° C. (for forming 9 nm oxide film). In this case, the peak concentration of as-implanted impurity profile is less than 5×10¹⁸ cm⁻³, which is the low concentration range, as shown in FIG. 7A. Accordingly, a value calculated based on the “+N” model is set as the generation number of interstitial atoms.

According to FIG. 14B, it is understood that the predicted profile 144 corresponding to the measured profile 143 can be obtained.

As described above, the invention is configured so that, in the high concentration range wherein a peak concentration of as-implanted impurity atoms is in exceed of a specific threshold value, the number of interstitial atoms to be generated by one implanted impurity atom is a value univocally determined based on only the impurity atom type and the peak concentration. Then, the concentration profile of impurity atoms after the thermal processing can be predicted by solving the well-known diffusion equation considering the interstitial point defects. That is to say, the manufacturing conditions of the semiconductor device reflected as the concentration profile of impurity atoms after the implantation, so that the accurate impurity diffusion simulation can be performed easily irrespective of the manufacturing conditions of the semiconductor device.

Moreover, the invention makes it possible to obtain the highly accurate impurity profile as for Boron and Phosphorous for which it is hard to obtain the accurate impurity profile.

The invention is not limited to the above-mentioned embodiment, but there are various modifications and applications as far as the effect of the invention can be obtained. For instance, the examples describes that the generation number of interstitial atoms in the low concentration range is calculated by using the “+N” model, however, it is possible to use the “+1” model instead of the “+N” model.

Even if the manufacturing method like the impurity implantation conditions and the thermal processing conditions are changed in arbitrary, the invention enables to predict the impurity profile accurately without optimizing the parameters again. Then, it is very useful for semiconductor process simulation which calculates impurity diffusion in semiconductor substrate.

1. An impurity diffusion simulation method for predicting concentration profile of ion-implanted impurity atoms in a semiconductor substrate, which is performed a thermal processing after ion-implantation, based on an impurity diffusion equation considering point defects, comprising the steps of:
calculating as-implanted concentration profile of impurity atoms in the semiconductor substrate;
setting a number of interstitial atoms to be generated in the semiconductor substrate by one impurity atom implanted with the ion implantation, based on a peak concentration of the calculated as-implanted concentration profile of impurity atoms;
calculating concentration profile of interstitial atoms generated in the semiconductor substrate based on the calculated as-implanted concentration profile of impurity atoms and the set generation number of interstitial atoms; and
calculating the concentration profile of impurity atoms in the semiconductor after the thermal processing, based on the calculated as-implanted concentration profile of impurity atoms and the calculated concentration profile of interstitial atoms.

2. An impurity diffusion simulation method according to claim 1, wherein,
the number of interstitial atoms to be generated by one impurity atom is set to a value, corresponding to a impurity atom type, determined univocally depending on only the peak concentration, when the peak concentration is a predetermined threshold value or more,
and
to a value univocally determined based on kinetic energy, mass, and projection range of the impurity atom, when the peak concentration is less than the predetermined threshold value.

3. An impurity diffusion simulation method according to claim 1, wherein,
the number of interstitial atoms to be generated by one impurity atom is set to a value, corresponding to a impurity atom type, determined univocally depending on only the peak concentration, when the peak concentration is a predetermined threshold value or more,
and
to a specific value, when the peak concentration is less than the predetermined threshold value.

4. An impurity diffusion simulation method according to claim 2, wherein a diffusion coefficient and a equilibrium concentration for the impurity diffusion equation are determined based on impurity concentration profile after the thermal processing in a real semiconductor substrate having the as-implanted peak concentration of impurity atoms less than the threshold value.

5. An impurity diffusion simulation method according to claim 3, wherein a diffusion coefficient and a equilibrium concentration for the impurity diffusion equation are determined based on impurity concentration profile after the thermal processing in a real semiconductor substrate having the as-implanted peak concentration of impurity atoms less than the threshold value.

6. An impurity diffusion simulation method according to claim 2, wherein the threshold value is 5×10¹⁸ cm⁻³.

7. An impurity diffusion simulation method according to claim 3, wherein the threshold value is 5×10¹⁸ cm⁻³.

8. An impurity diffusion simulation method according to claim 4, wherein the threshold value is 5×10¹⁸ cm⁻³.

9. An impurity diffusion simulation method according to claim 5, wherein the threshold value is 5×10¹⁸ cm⁻³.

10. An impurity diffusion simulation apparatus for predicting concentration profile of ion-implanted impurity atoms in a semiconductor substrate, which is performed a thermal processing after ion-implantation, based on an impurity diffusion equation considering point defects, comprising:
an unit configured to calculate as-implanted concentration profile of impurity atoms in the semiconductor substrate;
an unit configured to set a number of interstitial atoms to be generated in the semiconductor substrate by one impurity atom implanted with the ion implantation, based on a peak concentration of the calculated as-implanted concentration profile of impurity atoms;
an unit configured to calculate concentration profile of interstitial atoms generated in the semiconductor substrate based on the calculated as-implanted concentration profile of impurity atoms and the set generation number of interstitial atoms; and
an unit configured to calculate the concentration profile of impurity atoms in the semiconductor after the thermal processing, based on the calculated as-implanted concentration profile of impurity atoms and the calculated concentration profile of interstitial atoms.

11. An impurity diffusion simulation apparatus according to claim 10, wherein,
the unit configured to set the number of interstitial atoms to be generated sets the generation number to a value, corresponding to a impurity atom type, determined univocally depending on only the peak concentration, when the peak concentration is a predetermined threshold value or more,
and
sets the generation number to a value univocally determined based on kinetic energy, mass, and projection range of the impurity atom, when the peak concentration is less than the predetermined threshold value.

12. An impurity diffusion simulation apparatus according to claim 10, wherein,
the unit configured to set the number of interstitial atoms to be generated sets the generation number to a value, corresponding to a impurity atom type, determined univocally depending on only the peak concentration, when the peak concentration is a predetermined threshold value or more,
and
sets the generation number to a specific value, when the peak concentration is less than the predetermined threshold value.

13. An impurity diffusion simulation program, which causes a computer to execute the program for predicting concentration profile of ion-implanted impurity atoms in a semiconductor substrate, which is performed a thermal processing after ion-implantation, based on an impurity diffusion equation considering point defects, the program comprising the steps of:
calculating concentration profile of as-implanted impurity atoms in the semiconductor substrate;
setting a number of interstitial atoms to be generated in the semiconductor substrate by one impurity atom implanted with the ion implant, based on a peak concentration of the calculated as-implanted concentration profile of impurity atoms;
calculating concentration profile of interstitial atoms generated in the semiconductor substrate based on the calculated as-implanted concentration profile of impurity atoms and the set number of interstitial atoms;
and
calculating the concentration profile of impurity atoms in the semiconductor after the thermal processing, based on the calculated as-implanted concentration profile of impurity atoms and the calculated concentration profile of interstitial atoms.
